(19) United States
(12) Patent Application Publication
(10) Pub. No.: US 2018/0275225 A1
(43) Pub. Date: Sep. 27, 2018

(54) MAGNETO-OPTICAL DEFECT CENTER MATERIAL HOLDER

(71) Applicant: Lockheed Martin Corporation, Bethesda, MD (US)

(72) Inventor: Joseph W. Hahn, Erial, NJ (US)

(73) Assignee: Lockheed Martin Corporation, Bethesda, MD (US)

(21) Appl. No.: 15/468,559

(22) Filed: Mar. 24, 2017

(51) Int. Cl. G01R 33/26; G01R 33/032

(52) U.S. Cl. CPC G01R 33/26; G01R 33/032

(57) ABSTRACT

A magnetometer may include a housing and a light source configured to provide excitation light. The magnetometers may also include a magneto-optical defect center material with at least one defect center that emits light when excited by the excitation light. The magnetometers may further include a light sensor configured to receive the emitted light and a radio frequency circuit board configured to generate a radio frequency field around the magneto-optical defect center material. The magnetometers may also include a mount base. The magneto-optical defect center material and the radio frequency circuit board may be mounted to the mount base. The mount base can be configured to be fixed to the housing in a plurality of orientations.

### TECHNICAL FIELD

The present disclosure relates, in general, to magnetometers using magneto-optical defect center materials. More particularly, the present disclosure relates to a holder for the magneto-optical defect center material.

### BACKGROUND

The following description is provided to assist the understanding of the reader. None of the information provided or references cited is admitted to be prior art. Some magnetometers use magneto-optical defect center materials to determine a magnetic field. Such magnetometers can direct light into the magneto-optical defect center material. There is a desire for improving and optimizing a method for injecting light into the magneto-optical defect center materials while maintaining functionality of the magnetometer and/or adjustability of the magnetometer.

### SUMMARY

Some embodiments of a magnetometer may include a housing and a light source configured to provide excitation light. The magnetometers may also include a magneto-optical defect center material with at least one defect center that transmits emitted light when excited by the excitation light. The magnetometers may further include a light sensor configured to receive the emitted light and a radio frequency circuit board configured to generate a radio frequency field around the magneto-optical defect center material. The magnetometers may also include a mount base. The magneto-optical defect center material and the radio frequency circuit board may be mounted to the mount base. The mount base can be configured to be fixed to the housing in a plurality of orientations.

Some device embodiments include a magneto-optical defect center material with at least one defect center that transmits emitted light when excited by excitation light. The devices may also include a radio frequency circuit board that can be configured to generate a radio frequency field around the magneto-optical defect center material. The devices may further include a mount base. The magneto-optical defect center material and the radio frequency circuit board can be mounted to the mount base. The mount base may be configured to be fixed to a housing in a plurality of orientations.

The foregoing summary is illustrative only and is not intended to be in any way limiting. In addition to the illustrative aspects, embodiments, and features described above, further aspects, embodiments, and features will become apparent by reference to the following drawings and the detailed description.

### BRIEF DESCRIPTION OF THE DRAWINGS

FIG. 1 illustrates one orientation of a Nitrogen Vacancy (NV) center in a magneto-optical defect center material lattice in accordance with some illustrative embodiments.

FIG. 2 is an energy level diagram showing energy levels of spin states for an NV center in accordance with some illustrative embodiments.

FIG. 3 is a schematic diagram illustrating a NV center magnetic sensor system in accordance with some illustrative embodiments.

FIG. 4 is a graph illustrating fluorescence as a function of an applied RF frequency of an NV center along a given direction for a zero magnetic field in accordance with some illustrative embodiments.

FIG. 5 is a graph illustrating fluorescence as a function of an applied RF frequency for four different NV center orientations for a non-zero magnetic field in accordance with some illustrative embodiments.

FIG. 6 is a schematic diagram illustrating a magnetic field detection system in accordance with some illustrative embodiments.

FIG. 7 is an illustration of an inside view of a magnetometer in accordance with some illustrative embodiments.

FIGS. 8A-8C are three-dimensional views of an element holder assembly in accordance with some illustrative embodiments.

FIG. 9 is a circuit outline of a radio frequency element circuit board in accordance with some illustrative embodiments.

FIGS. 10A and 10B are three-dimensional views of an element holder base in accordance with some illustrative embodiments.

The foregoing and other features of the present disclosure will become apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and make part of this disclosure.

Magnetometers can use a magneto optical defect center material to determine a magnitude and direction of an external magnetic field. For example, the magneto optical defect center material can be a diamond with NV centers. In other examples, any other suitable material with defect centers may be used. As discussed in greater detail below, a radio frequency field with varying frequencies over time is applied to the magneto optical defect center to determine the external magnetic field. In some instances, the magneto-optical defect center material 320 has multiple sides that light can be passed through.

It can be advantageous to change the side of the magneto optical defect center material that the light is injected to. As described in greater detail below, differing uniformity or number of defect centers being excited can adjust the sensitivity of the magnetometer. In various embodiments described herein, a magneto optical defect center material holder is provided that allows an easy or convenient method of changing the side of the magneto optical defect center material that the light is injected into.

In some illustrative embodiments, a copper base is provided with multiple mounting holes. The copper base can have an area for mounting the magneto optical defect center material and an antenna for bathing the magneto optical defect center material in a radio frequency (RF) field. Accordingly, the magneto optical defect center material holder can also include an attachment for receiving the RF signal. The magneto optical defect center material holder can be mounted in multiple orientations that allow light to be injected into different sides of the magneto optical defect center material.

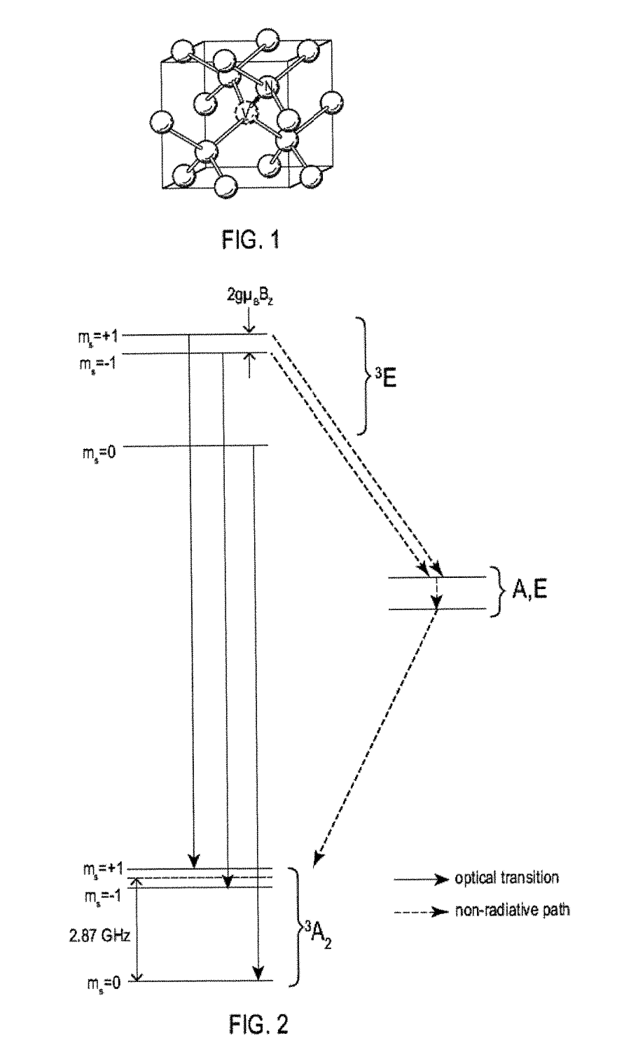

The NV center in a diamond comprises a substitutional nitrogen atom in a lattice site adjacent a carbon vacancy as shown in FIG. 1. The NV center may have four orientations, each corresponding to a different crystallographic orientation of the diamond lattice. Although FIG. 1 shows the NV center in a diamond, the same or similar principals can be applied to defect centers in any suitable magneto-optical defect center material.

The NV center may exist in a neutral charge state or a negative charge state. Conventionally, the neutral charge state uses the nomenclature NV⁰, while the negative charge state uses the nomenclature NV, which is adopted in this description.

The NV center has a number of electrons, including three unpaired electrons, each one from the vacancy to a respective of the three carbon atoms adjacent to the vacancy, and a pair of electrons between the nitrogen and the vacancy. The NV center, which is in the negatively charged state, also includes an extra electron.

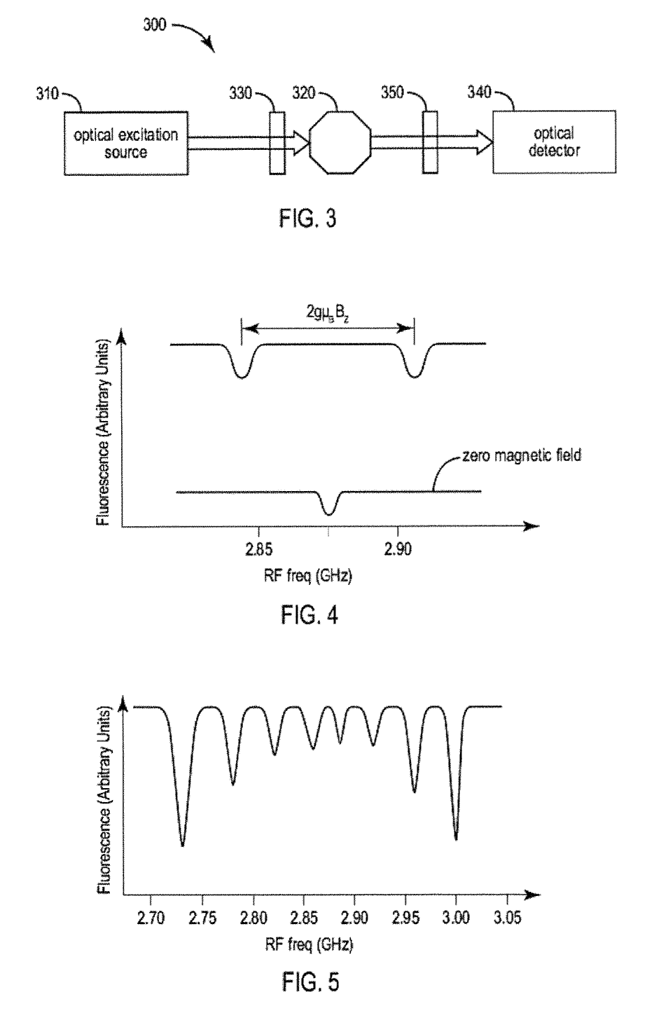

The NV center has rotational symmetry, and as shown in FIG. 2, has a ground state, which is a spin triplet with ³A₂ symmetry with one spin state mₛ=0, and two further spin states mₛ=+1, and mₛ=−1. In the absence of an external magnetic field, the mₛ=±1 energy levels are offset from the mₛ=0 due to spin-spin interactions, and the mₛ=±1 energy levels are degenerate, i.e., they have the same energy. The mₛ=0 spin state energy level is split from the mₛ=±1 energy levels by an energy of 2.87 GHz for a zero external magnetic field.

Introducing an external magnetic field with a component along the NV axis lifts the degeneracy of the mₛ=±1 energy levels, splitting the energy levels mₛ=±1 by an amount 2 gμ_{B}Bz, where g is the g-factor, μ_{B} is the Bohr magneton, and Bz is the component of the external magnetic field along the NV axis. This relationship is correct to a first order and inclusion of higher order corrections is a straightforward matter and will not affect the computational and logic steps in the systems and methods described below.

The NV center electronic structure further includes an excited triplet state ³E with corresponding mₛ=0 and mₛ=±1 spin states. The optical transitions between the ground state ³A₂ and the excited triplet ³E are predominantly spin conserving, meaning that the optical transitions are between initial and final states that have the same spin. For a direct transition between the excited triplet ³E and the ground state ³A₂, a photon of red light is emitted with a photon energy corresponding to the energy difference between the energy levels of the transitions.

There is, however, an alternative non-radiative decay route from the triplet ³E to the ground state ³A₂ via intermediate electron states, which are thought to be intermediate singlet states A, E with intermediate energy levels. Significantly, the transition rate from the mₛ=±1 spin states of the excited triplet ³E to the intermediate energy levels is significantly greater than the transition rate from the mₛ=0 spin state of the excited triplet ³E to the intermediate energy levels. The transition from the singlet states A, E to the ground state triplet ³A₂ predominantly decays to the mₛ=0 spin state over the mₛ=±1 spins states. These features of the decay from the excited triplet ³E state via the intermediate singlet states A, E to the ground state triplet ³A₂ allows that if optical excitation is provided to the system, the optical excitation will eventually pump the NV center into the mₛ=0 spin state of the ground state ³A₂. In this way, the population of the mₛ=0 spin state of the ground state ³A₂ may be “reset” to a maximum polarization determined by the decay rates from the triplet ³E to the intermediate singlet states.

Another feature of the decay is that the fluorescence intensity due to optically stimulating the excited triplet ³E state is less for the mₛ=±1 states than for the mₛ=0 spin state. This is so because the decay via the intermediate states does not result in a photon emitted in the fluorescence band, and because of the greater probability that the mₛ=±1 states of the excited triplet ³E state will decay via the non-radiative decay path. The lower fluorescence intensity for the mₛ=±1 states than for the mₛ=0 spin state allows the fluorescence intensity to be used to determine the spin state. As the population of the mₛ=±1 states increases relative to the mₛ=0 spin, the overall fluorescence intensity will be reduced.

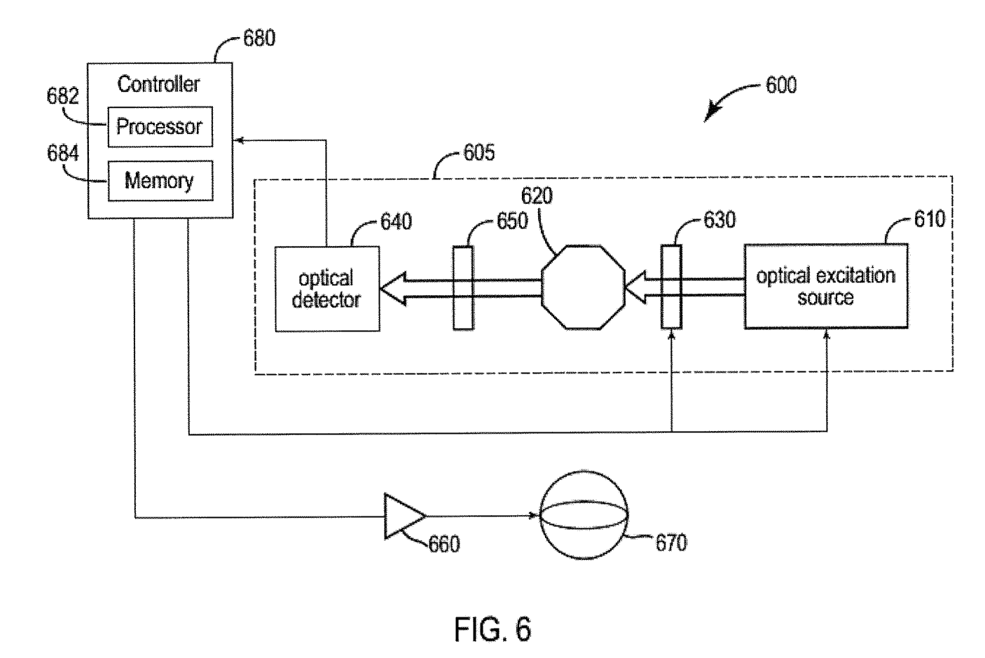

FIG. 3 is a schematic diagram illustrating a conventional magneto-optical defect center material magnetic sensor system 300 that uses fluorescence intensity to distinguish the mₛ=±1 states, and to measure the magnetic field based on the energy difference between the mₛ=+1 state and the mₛ=−1 state. The system 300 includes an optical excitation source 310, which directs optical excitation to a magneto-optical defect center material 320 with defect centers. The system further includes an RF excitation source 330, which provides RF radiation to the magneto-optical defect center material 320. Light from the magneto-optical defect center material may go through an optical filter 350 to an optical detector 340.

The RF excitation source 330 may be a microwave coil, for example. The RF excitation source 330, when emitting RF radiation with a photon energy resonant with the transition energy between ground mₛ=0 spin state and the mₛ=+1 spin state, excites a transition between those spin states. For such a resonance, the spin state cycles between ground mₛ=0 spin state and the mₛ=+1 spin state, reducing the population in the mₛ=0 spin state and reducing the overall fluorescence at resonances. Similarly, resonance occurs between the mₛ=0 spin state and the mₛ=−1 spin state of the ground state when the photon energy of the RF radiation emitted by the RF excitation source is the difference in energies of the mₛ=0 spin state and the mₛ=−1 spin state, or between the mₛ=0 spin state and the mₛ=+1 spin state, there is a decrease in the fluorescence intensity.

The optical excitation source 310 may be a laser or a light emitting diode, for example, which emits light in the green, for example. The optical excitation source 310 induces fluorescence in the red, which corresponds to an electronic transition from the excited state to the ground state. Light from the magneto-optical defect center material 320 is directed through the optical filter 350 to filter out light in the excitation band (in the green, for example), and to pass light in the red fluorescence band, which in turn is detected by the detector 340. The optical excitation light source 310, in addition to exciting fluorescence in the magneto-optical defect center material 320, also serves to reset the population of the mₛ=0 spin state of the ground state ³A₂ to a maximum polarization, or other desired polarization.

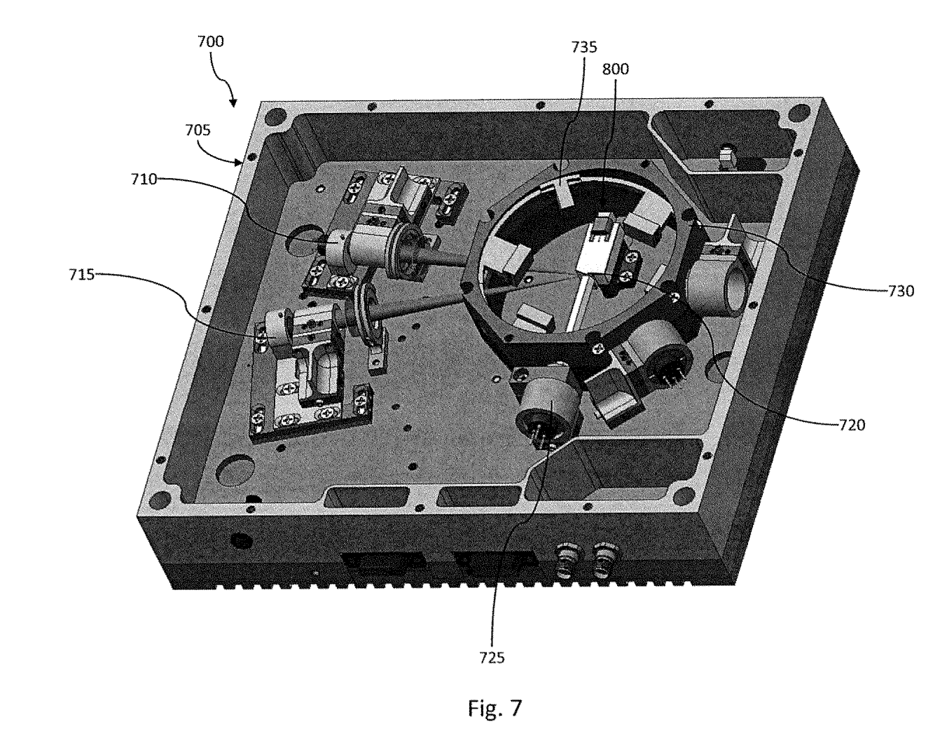

For continuous wave excitation, the optical excitation source 310 continuously pumps the defect centers, and the RF excitation source 330 emits an RF field that sweeps across a frequency range that includes the zero splitting (when the mₛ=±1 spin states have the same energy) photon energy of 2.87 GHz. In some illustrative embodiments, the light does not pass through the RF excitation source 330. The light from optical excitation source 310 passes in front of RF excitation source 330. The fluorescence for an RF sweep corresponding to a magneto-optical defect center material 320 with defect centers aligned along a single direction is shown in FIG. 4 for different magnetic field components Bz along the defect axis, where the energy splitting between the mₛ=−1 spin state and the mₛ=+1 spin state increases with Bz. Thus, the component Bz may be determined. Optical excitation schemes other than continuous wave excitation are contemplated, such as excitation schemes involving pulsed optical excitation, and pulsed RF excitation. Examples of pulsed excitation schemes include Ramsey pulse, and spin echo pulse sequence.

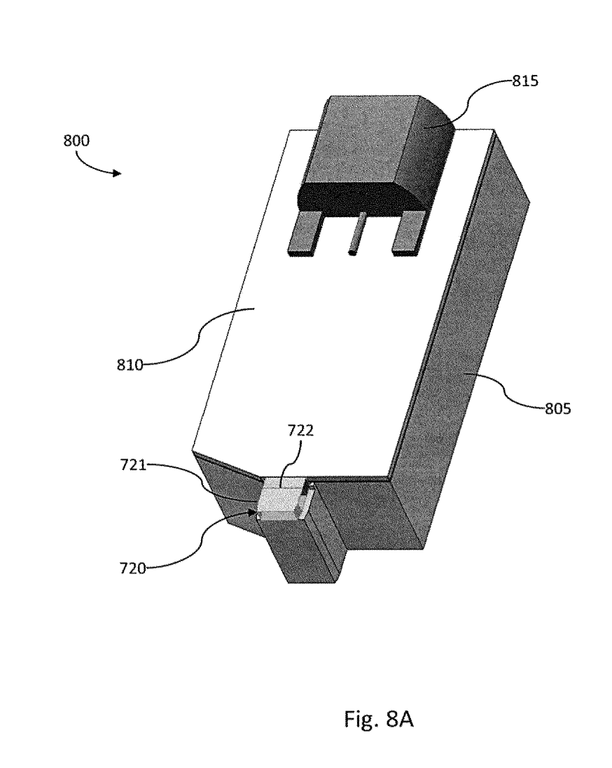

In general, the magneto-optical defect center material 320 may have defect centers aligned along directions of four different orientation classes. FIG. 5 illustrates fluorescence as a function of RF frequency for the case where the magneto-optical defect center material 320 has defect centers aligned along directions of four different orientation classes. In this case, the component Bz along each of the different orientations may be determined. These results, along with the known orientation of crystallographic planes of a magneto-optical defect center material lattice, allow not only the magnitude of the external magnetic field to be determined, but also the direction of the magnetic field.

FIG. 3 illustrates a defect center magnetic sensor system 300 with magneto-optical defect center material 320 with a plurality of defect centers, in general. The magnetic sensor system 300 may employ any suitable magneto-optical defect center material with a plurality of magneto-optical defect centers. The electronic spin state energies of the magneto-optical defect centers shift with magnetic field, and the optical response, such as fluorescence, for the different spin states is not the same for all of the different spin states. In this way, the magnetic field may be determined based on optical excitation, and possibly RF excitation.

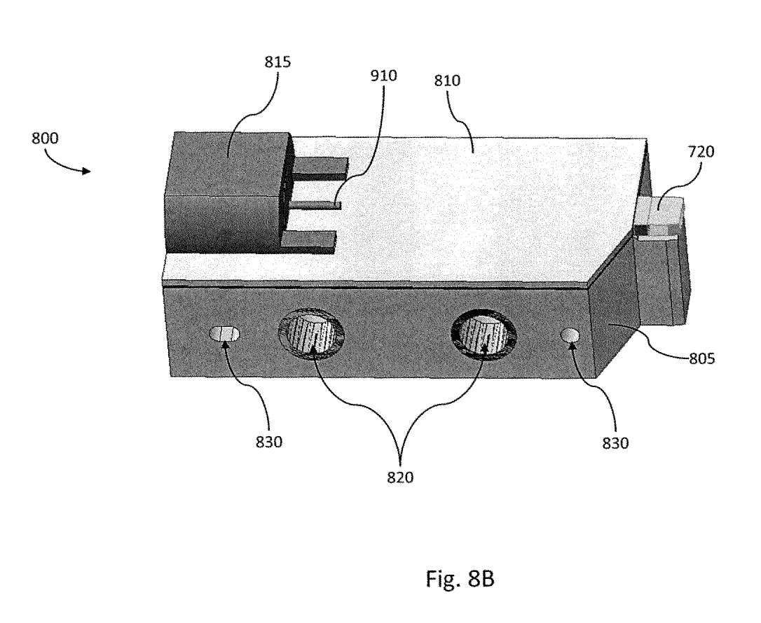

FIG. 6 is a schematic diagram of a system 600 for a magnetic field detection system according to some embodiments. The system 600 includes an optical excitation source 610, which directs optical excitation to a magneto-optical defect center material 620 with defect centers. An RF excitation source 630 provides RF radiation to the magneto-optical defect center material 620. A magnetic field generator 670 generates a magnetic field, which is detected at the magneto-optical defect center material 620.

The magnetic field generator 670 may generate magnetic fields with orthogonal polarizations, for example. In this regard, the magnetic field generator 670 may include two or more magnetic field generators, such as two or more Helmholtz coils. The two or more magnetic field generators may be configured to provide a magnetic field having a predetermined direction, each of which provide a relatively uniform magnetic field at the magneto-optical defect center material 620. The predetermined directions may be orthogonal to one another. In addition, the two or more magnetic field generators of the magnetic field generator 670 may be disposed at the same position, or may be separated from each other. In the case that the two or more magnetic field generators are separated from each other, the two or more magnetic field generators may be arranged in an array, such as a one-dimensional or two-dimensional array, for example.

The system 600 may be arranged to include one or more optical detection systems 605, where each of the optical detection systems 605 includes the optical detector 640, optical excitation source 610, and Magneto-optical defect center material 620. Furthermore, the magnetic field generator 670 may have a relatively high power as compared to the optical detection systems 605. In this way, the optical systems 605 may be deployed in an environment that requires a relatively lower power for the optical systems 605, while the magnetic field generator 670 may be deployed in an environment that has a relatively high power available for the magnetic field generator 670 so as to apply a relatively strong magnetic field.

The system 600 further includes a controller 680 arranged to receive a light detection signal from the optical detector 640 and to control the optical excitation source 610, the RF excitation source 630, and a second magnetic field generator (not shown in FIG. 6). The controller may be a single controller, or multiple controllers. For a controller including multiple controllers, each of the controllers may perform different functions, such as controlling different components of the system 600. The second magnetic field generator may be controlled by the controller 680 via an amplifier 660, for example.

The RF excitation source 630 may be a microwave coil, for example behind the light of the optical excitation source 610. The RF excitation source 630 is controlled to emit RF radiation with a photon energy resonant with the transition energy between the ground mₛ=0 spin state and the mₛ=±1 spin states as discussed above with respect to FIG. 3.

The optical excitation source 610 may be a laser or a light emitting diode, for example, which emits light in the green, for example. The optical excitation source 610 induces fluorescence in the red from the Magneto-optical defect center material 620, where the fluorescence corresponds to an electronic transition from the excited state to the ground state. Light from the Magneto-optical defect center material 620 is directed through the optical filter 650 to filter out light in the excitation band (in the green, for example), and to pass light in the red fluorescence band, which in turn is detected by the optical detector 640. The optical excitation light source 610, in addition to exciting fluorescence in the Magneto-optical defect center material 620, also serves to reset the population of the mₛ=0 spin state of the ground state ³A₂ to a maximum polarization, or other desired polarization.

The controller 680 is arranged to receive a light detection signal from the optical detector 640 and to control the optical excitation source 610, the RF excitation source 630, and the second magnetic field generator (not shown in FIG. 6). The controller may include a processor 682 and a memory 684, in order to control the operation of the optical excitation source 610, the RF excitation source 630, and the second magnetic field generator. The memory 684, which may include a nontransitory computer readable medium, may store instructions to allow the operation of the optical excitation source 610, the RF excitation source 630, and the second magnetic field generator to be controlled. That is, the controller 680 may be programmed to provide control.

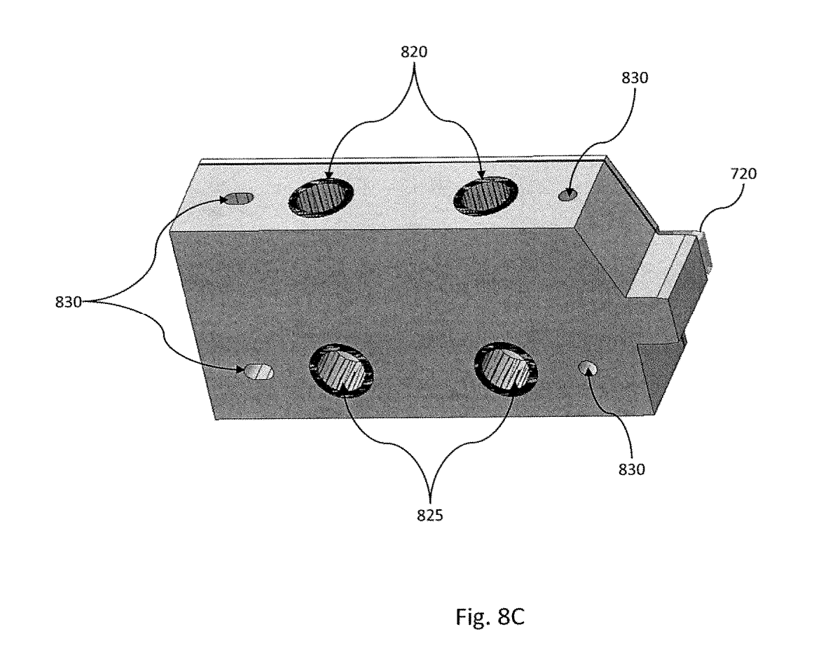

FIG. 7 is an illustration of an inside view of a magnetometer in accordance with some illustrative embodiments. An illustrative magnetometer 700 includes a housing 705, light sources 710 and 715, a magneto-optical defect center material 720, a light detector 725, a magnet ring mount 730, and a bias magnet ring 735. In alternative embodiments, additional, fewer, and/or different elements may be used. For example, although two light sources 710 and 715 are shown in the embodiment of FIG. 7, any suitable number of light sources can be used, such as one, three, four, etc. light sources.

As noted above, a bias magnetic field may be applied to the magneto-optical defect center material 720. In the embodiment illustrated in FIG. 7, permanent magnets are mounted to the bias magnet ring 735, which is secured within the magnet ring mount 730. The magnet ring mount 730 is mounted or fixed within the housing 705 such that the magnet ring mount 730 does not move within the housing 705. Similarly, the light sources 710 and 715 are mounted within the housing 705 such that the light sources 710 and 715 do not move within the housing 705.

As shown in FIG. 7, the magneto-optical defect center material 720 is mounted within the magnetic ring mount 730, but the light sources 710 are mounted outside of the magnetic ring mount 730. The light sources 710 transmit light to the magneto-optical defect center material 720 which excites the defect centers, and light emitted from the defect centers is detected by the light detector 725. In some embodiments shown in FIG. 7, the light sources 710 and 715 transmit the light such that the magnet ring mount 730 and the bias magnet ring 735 do not interfere with the transmission of the light from the light sources 710 and 715 to the magneto-optical defect material 720.

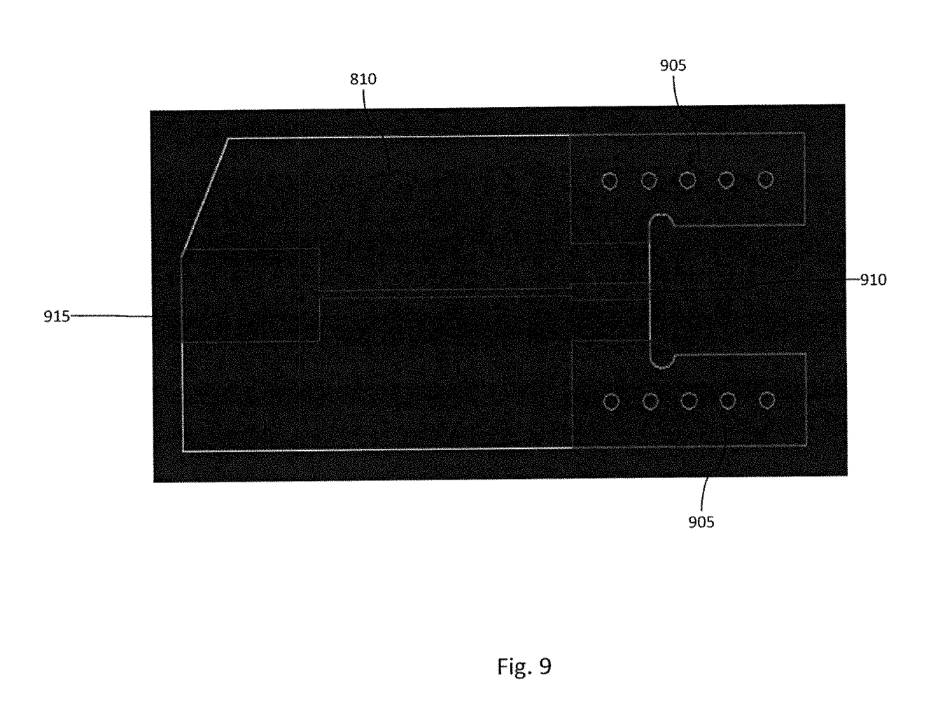

FIGS. 8A-8C are three-dimensional views of an element holder assembly in accordance with some illustrative embodiments. An illustrative magneto-optical defect center material holder 800 includes the magneto-optical defect center material 720, a base 805, a radio frequency (RF) circuit board 810, an RF signal connector 815, first mounting holes 820, and second mounting holes 825. In the embodiment illustrated in FIGS. 8A-8C, the magneto-optical defect center material holder 800 includes locating slots 830. In alternative embodiments, additional, fewer, and/or different elements may be used.

As shown in FIG. 8A, the magneto-optical defect center material 720 is attached to the base 805. The magneto-optical defect center material 720 can be mounted to the base 805 using any suitable securing mechanism, such as a glue or an epoxy. In alternative embodiments, screws, bolts, clips, fasteners, or etc. may be used. In some embodiments, the magneto-optical defect center material 720 can be fixed to the RF circuit board 810. For example, a ribbon bond can be used between the magneto-optical defect center material 720 and the RF circuit board 810. In alternative embodiments, any other suitable methods can be used to attach the magneto-optical defect center material 720 to the RF circuit board 810.

In the embodiment shown in FIG. 8A, one side of the magneto-optical defect center material 720 is adjacent to the base 805, and one side of the magneto-optical defect center material 720 is adjacent to the RF circuit board 820. In such an embodiment, other sides of the magneto-optical defect center material 720 are not adjacent to opaque objects and, therefore, can have light injected therethrough. In the embodiment shown in FIG. 8A, the magneto-optical defect center material 720 has eight sides, six of which are not adjacent to an opaque object. In alternative embodiments, the magneto-optical defect center material 720 can have greater than or fewer than eight sides.

For example, the magneto-optical defect center material 720 includes two sides 721 and 722 through which light can be injected into the magneto-optical defect center material 720. In such an example, light can be injected through the edge side 721 or the face side 722. When light is injected through the edge side 721, the defect centers in the magneto-optical defect center material 720 are excited less uniformly than when light is injected through the face side 722. Also, when light is injected through the edge side 721, more of the defect centers in the magneto-optical defect center material 720 are excited than when light is injected through the face side 722.

In some illustrative embodiments, the more of the defect centers in the magneto-optical defect center material 720 are excited by light, the more red light is emitted from the magneto-optical defect center material 720. In some illustrative embodiments, the more uniformly that the defect centers in the magneto-optical defect center material 720 are excited by the light the more sensitive the magnetometer may be. Thus, in some instances, it may be preferential to inject light into the edge side 721 while in other instances it may be preferential to inject light into the face side 722.

In the embodiment shown in FIG. 8A, the side of the magneto-optical defect center material 720 opposite the edge face 721 is not obstructed by an opaque object (e.g., base 805 or the RF circuit board 810). That is, light injected into the edge face 721 that is not absorbed by defect centers (e.g., used to excite defect centers) of the magneto-optical defect center material 720 may pass through the magneto-optical defect center material 720. In an illustrative embodiment the light that passes through the magneto-optical defect center material 720 may be sensed by an optical sensor. The light that passes through the magneto-optical defect center material 720 may be used to eliminate or reduce correlated noise in the light captured by the light detector 725.

In the embodiment shown in FIG. 8A, the side of the magneto-optical defect center material 720 that is opposite the face edge 722 is adjacent to the base 805. Thus, light that is injected through the face edge 722 that is not absorbed by defect centers is absorbed by the base 805. That is, the light not absorbed by the defect centers is not detected by a light detector to be used to eliminate or reduce correlated noise. In some alternative embodiments, the base 805 includes a through hole that unabsorbed light can pass through.

As shown in FIG. 8B, the base 805 can include first mounting holes 820. As shown in FIG. 8C, the base 805 can include second mounting holes 825. The first mounting holes 820 and the second mounting holes 820 can be configured to accept mounting means, such as a screw, a bolt, a clip, a fastener, etc. In some illustrative embodiments, the mounting holes 820 are threaded. For example, a helical insert can be used to provide threaded means for accepting a screw or bolt. In some illustrative embodiments, the helical insert can be made of brass, steel, stainless steel, aluminum, nylon, plastic, etc. For example, the threaded inserts can have #2-56 threads. In alternative embodiments, the threaded inserts can have any other suitable threads. The first mounting holes 820 can be used to secure the side of the base 820 with the first mounting holes 820 against a base of the housing 705. Thus, in the embodiment shown in FIG. 7, when the base 820 is mounted to the housing 705 via the first mounting holes 820, light from the light sources 710 and 715 can be injected through the face side 722 of the magneto-optical defect center material 720. Similarly, when the base 820 is mounted to the housing 705 via the second mounting holes 825, light from the light sources 710 and 715 can be injected through the edge side 721.

In some illustrative embodiments, the base 805 can include slots 830. The slots 830 can be used to receive pegs or other inserts that are attached to the housing 705. In such embodiments, the slots 830 can be used to align the base 805 with holes or fasteners associated with the first mounting holes 820 or the second mounting holes 825. Thus, the magneto-optical defect center material holder 820 can easily and/or conveniently be rotated to optionally mount to the housing 705 via either the first mounting holes 820 or the second mounting holes 825. In alternative embodiments, the magneto-optical defect center material holder 800 can include additional sets of mounting holes. Also, although the embodiments shown in FIGS. 8A-8C include two holes in each set of the first mounting holes 820 and the second mounting holes 825, any other suitable number of mounting holes can be used.

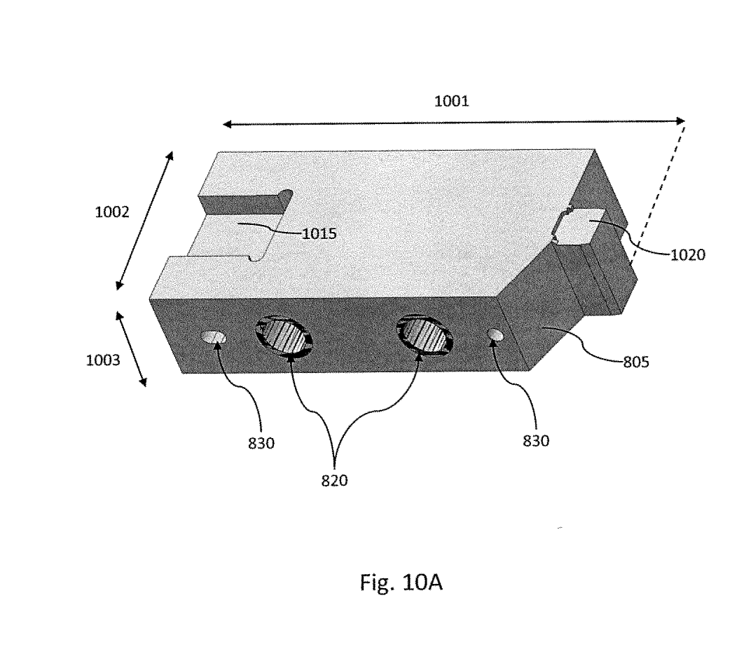

FIG. 9 is a circuit outline of a radio frequency element circuit board in accordance with some illustrative embodiments. An illustrative example RF element circuit board 810 can include a positive electrode 910, an RF signal trace 915, and ground connectors 905. In alternative embodiments, additional, fewer, and/or different elements may be used. As shown in FIG. 8A, the RF element circuit board 810 can be attached to the base 805. The RF circuit board 810 can be attached to the base 805 using any suitable method, such as via a glue, epoxy, screws, bolts, clips, fasteners, etc.

As discussed above, an RF field can be applied to the magneto-optical defect center material 720 to determine the external magnetic field. In some illustrative embodiments, the RF signal connector 815 can be configured to receive a connector or cable over which an RF signal is transmitted. For example, the RF signal connector 815 can be configured to accept a coaxial cable. The positive electrical connection of the RF signal connector 815 can be connected to the positive electrode 910. The positive electrode 910 can, in turn, be electrically connected to the RF signal trace 915. Similarly, the ground connection from the RF signal connector 815 can be electrically connected to the ground connectors 905. In some illustrative embodiments, the ground connectors 905 are electrically connected to the base 805, which can be connected to a ground of the magnetometer 700. Thus, an RF signal transmitted to the RF signal connector 815 can be transmitted through the RF signal trace 915, which can transmit an RF field. The RF field can be applied to the magneto-optical defect center material 720. Thus, the signal transmitted to the RF signal connector 815 can be used to apply the RF field to the magneto-optical defect center material 720.

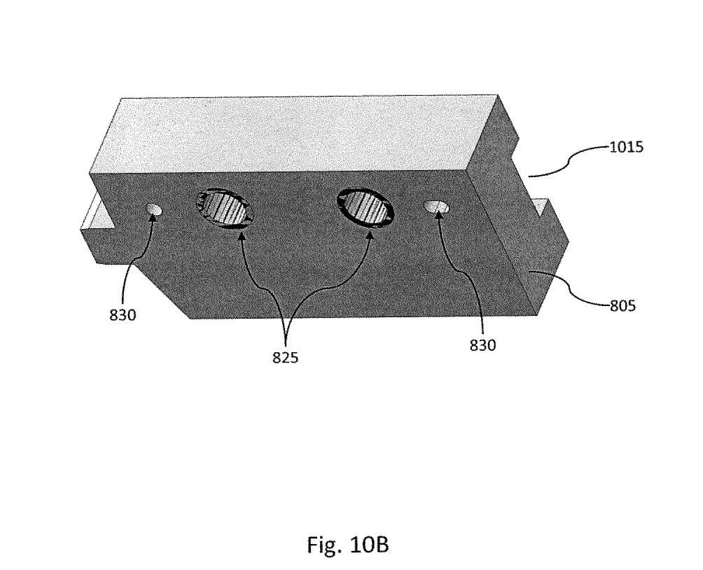

FIGS. 10A and 10B are three-dimensional views of an element holder base in accordance with some illustrative embodiments. An illustrative base 805 includes the first mounting holes 820, the second mounting holes 825, the slots 830, an RF connector recess 1015, and a magneto-optical defect center material recess 1020. In alternative embodiments, additional, fewer, and/or different elements may be used.

In some illustrative embodiments, the base 805 is made of a conductive material. For example, the base 805 may be made of brass, steel, stainless steel, aluminum, etc.

The base 805 can include an RF connector recess 1015 that can be configured to accept at least a portion of the RF signal connector 815. Similarly, the magneto-optical defect center material recess 1015 can be configured to accept the magneto-optical defect center material 720. For example, the magneto-optical defect center material 720 can be mounted to the magneto-optical defect center material recess 1020.

In some illustrative embodiments, the length 1001 (e.g., from the edge of the base 805 with the RF connector recess 1015 to the edge with the magneto-optical defect center material recess 1020, as shown by the dashed line) of the base 805 is 0.877 inches long. In alternative embodiments, the length 1001 can be less than or greater than 0.877 inches. In some illustrative embodiments, the width 1002 is 0.4 inches. In alternative embodiments, the width 1002 is less than or greater than 0.4 inches. In some illustrative embodiments, the height 1003 is 0.195 inches. In alternative embodiments, the height 1003 is less than or greater than 0.195 inches.

In an illustrative embodiment, any of the operations described herein can be implemented at least in part as computer-readable instructions stored on a computer-readable memory. Upon execution of the computer-readable instructions by a processor, the computer-readable instructions can cause a node to perform the operations.

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality, and any two components capable of being so associated can also be viewed as being “operably couplable,” to each other to achieve the desired functionality. Specific examples of operably couplable include but are not limited to physically mateable and/or physically interacting components and/or wirelessly interactable and/or wirelessly interacting components and/or logically interacting and/or logically interactable components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.” Further, unless otherwise noted, the use of the words “approximate,” “about,” “around,” “substantially,” etc., mean plus or minus ten percent.

The foregoing description of illustrative embodiments has been presented for purposes of illustration and of description. It is not intended to be exhaustive or limiting with respect to the precise form disclosed, and modifications and variations are possible in light of the above teachings or may be acquired from practice of the disclosed embodiments. It is intended that the scope of the invention be defined by the claims appended hereto and their equivalents.

What is claimed is:

1. A magnetometer comprising:
a housing;
a light source configured to provide excitation light;
a magneto-optical defect center material with at least one defect center that emits light when excited by the excitation light;
a light sensor configured to receive the emitted light;
a radio frequency circuit board configured to generate a radio frequency field around the magneto-optical defect center material; and
a mount base, wherein the magneto-optical defect center material and the radio frequency circuit board are mounted to the mount base, and wherein the mount base is configured to be fixed to the housing in a plurality of orientations.

2. The magnetometer of claim 1, wherein, in each of the plurality of orientations, the excitation light enters the magneto-optical defect center material in a respective side of the magneto-optical defect center material.

3. The magnetometer of claim 1, wherein the excitation light is injected into a first side of the magneto-optical defect center material when the mount base is fixed in a first orientation in the plurality of orientations, and wherein the excitation light is injected into a second side of the magneto-optical defect center material when the mount base is fixed in a second orientation in the plurality of orientations.

4. The magnetometer of claim 3, wherein, when the mount base is fixed in the first orientation, a portion of the excitation light passes through the magneto-optical defect center material and is detected by a second light sensor, and wherein, when the mount base is fixed in the second orientation, a portion of the excitation light is not detected by the second light sensor.

5. The magnetometer of claim 1, wherein the mount base is configured to be fixed to the housing in the plurality of orientations via a plurality of sets of fixation holes.

6. The magnetometer of claim 5, wherein each of the fixation holes of the sets of fixation holes comprises a threaded hole.

7. The magnetometer of claim 6, wherein the mount base is configured to be fixed to the housing via at least one threaded shaft.

8. The magnetometer of claim 5, wherein each set of the plurality of sets of fixation holes comprises two fixation holes.

9. The magnetometer of claim 5, wherein each set of the plurality of sets of fixation holes is two fixation holes.

10. The magnetometer of claim 1, wherein the light source and the light sensor are fixed to the housing.

11. The magnetometer of claim 1, further comprising a processor configured to:
receive an indication of a frequency of the excitation light;
receive an indication of a frequency of the emitted light; and
determine a magnitude of an external magnetic field based at least in part on a comparison between the frequency of the excitation light and the frequency of the emitted light.

12. The magnetometer of claim 11, wherein the processor is further configured to determine a direction of the external magnetic field based at least in part on a comparison between the frequency of the excitation light and the frequency of the emitted light.

13. The magnetometer of claim 11, wherein the processor is further configured to determine the magnitude of the external magnetic field based in part on the radio frequency field.

14. The magnetometer of claim 13, wherein the radio frequency field has a frequency that is time-varying.

15. The magnetometer of claim 1, wherein a frequency of the excitation light is different than a frequency of the emitted light.

16. A device comprising:
a magneto-optical defect center material with at least one defect center that emits light when excited by excitation light;
a radio frequency circuit board configured to generate a radio frequency field around the magneto-optical defect center material; and
a mount base, wherein the magneto-optical defect center material and the radio frequency circuit board are mounted to the mount base, and wherein the mount base is configured to be fixed to a housing in a plurality of orientations.

17. The device of claim 16, wherein, in each of the plurality of orientations, the excitation light enters the magneto-optical defect center material in a respective side of the magneto-optical defect center material.

18. The device of claim 16, wherein the excitation light is injected into a first side of the magneto-optical defect center material when the mount base is fixed in a first orientation in the plurality of orientations, and wherein the excitation light is injected into a second side of the magneto-optical defect center material when the mount base is fixed in a second orientation in the plurality of orientations.

19. The device of claim 18, wherein, when the mount base is fixed in the first orientation, a portion of the excitation light passes through the magneto-optical defect center material and is detected by a light sensor, and wherein, when the mount base is fixed in the second orientation, a portion of the excitation light is not detected by the light sensor.

20. The device of claim 16, wherein the mount base is configured to be fixed to the housing in the plurality of orientations via a plurality of sets of fixation holes.

21. The device of claim 20, wherein each of the fixation holes of the sets of fixation holes comprises a threaded hole.

22. The device of claim 21, wherein the mount base is configured to be fixed to the housing via at least one threaded shaft.

23. The device of claim 20, wherein each set of the plurality of sets of fixation holes comprises two fixation holes.

24. The device of claim 20, wherein each set of the plurality of sets of fixation holes is two fixation holes.

25. The device of claim 16, wherein a frequency of the excitation light is different than a frequency of the emitted light.

26. A device for facilitating injection of light into multiple sides of a magneto-optical material, the device comprising:
the magneto-optical material that is capable of fluorescing upon the application of certain light and upon applied radio frequency (RF) fields;
a radio frequency (RF) circuit board configured to generate the RF fields; and
a mount base to which the RF circuit board and the magneto-optical material are fixed, wherein the mount base is mountable to a housing of a magnetometer in a plurality of orientations.

27. The device of claim 26, wherein, in each of the plurality of orientations, the excitation light enters the magneto-optical defect center material in a respective side of the magneto-optical defect center material.

28. The device of claim 26, wherein the excitation light is injected into a first side of the magneto-optical defect center material when the mount base is fixed in a first orientation in the plurality of orientations, and wherein the excitation light is injected into a second side of the magneto-optical defect center material when the mount base is fixed in a second orientation in the plurality of orientations.

29. The device of claim 28, wherein, when the mount base is fixed in the first orientation, a portion of the excitation light passes through the magneto-optical defect center material and is detected by a light sensor, and wherein, when the mount base is fixed in the second orientation, a portion of the excitation light is not detected by the light sensor.

30. The device of claim 26, wherein the mount base is configured to be fixed to the housing in the plurality of orientations via a plurality of sets of fixation holes.

31. The device of claim 30, wherein each of the fixation holes of the sets of fixation holes comprises a threaded hole.

32. The device of claim 31, wherein the mount base is configured to be fixed to the housing via at least one threaded shaft.

33. The device of claim 30, wherein each set of the plurality of sets of fixation holes comprises two fixation holes.

34. The device of claim 30, wherein each set of the plurality of sets of fixation holes is two fixation holes.

35. The device of claim 26, wherein a frequency of the excitation light is different than a frequency of the emitted light.
